(19) United States
(12) Patent Application Publication
(10) Pub. No.: US 2024/0027497 A1
(43) Pub. Date: Jan. 25, 2024

(54) HIGH SPEED WAVEFORM ACQUISITIONS AND HISTOGRAMS USING GRAPHICS PROCESSING UNIT IN A TEST AND MEASUREMENT INSTRUMENT

(71) Applicant: Tektronix, Inc., Beaverton, OR (US)

(72) Inventors: Andy K. Lim, Tigard, OR (US); Daniel G. Knierim, Beaverton, OR (US)

(73) Assignee: Tektronix, Inc., Beaverton, OR (US)

(21) Appl. No.: 18/353,638

(22) Filed: Jul. 17, 2023

Related U.S. Application Data
(60) Provisional application No. 63/391,288, filed on Jul. 21, 2022.

(51) Int. Cl. G01R 13/02; G06T 1/20

(52) U.S. Cl. CPC G01R 13/0218; G01R 13/029; G06T 1/20

(57) ABSTRACT

A test and measurement instrument has an acquisition system to receive and digitize a batch of waveforms into a batch of digitized waveforms, a memory configured as a raster plane having rows and columns, a graphics processing unit (GPU) capable of processing multiple threads to rasterize the batch of digitized waveforms to the raster plane to form a batch histogram and to group multiple threads into groups of a first type of group, assign each thread group of the first type of group to one column in the raster plane, execute a common instruction per thread group of the first type to populate the raster plane, and transfer the batch histogram upon completion, and a central processing unit (CPU) to receive the batch histogram from the GPU, and display a map of the batch histogram on a display.

### CROSS-REFERENCE TO RELATED APPLICATIONS

This disclosure claims benefit of U.S. Provisional Application No. 63/391,288, titled “HIGH SPEED WAVEFORM ACQUISITIONS AND HISTOGRAMS USING GRAPHICS PROCESSING UNIT IN A TEST AND MEASUREMENT INSTRUMENT,” filed on Jul. 21, 2022, the disclosure of which is incorporated herein by reference in its entirety.

### TECHNICAL FIELD

This disclosure relates to test and measurement instruments, and more particularly to using a graphics processing unit in a test and measurement instrument such as an oscilloscope.

### BACKGROUND

Under the Nyquist criterion, one can correctly reconstruct a repetitive waveform provided that the sampling frequency is greater than double the highest frequency to be sampled. A digital oscilloscopes' sample rate must increase to resolve the ever-increasing higher frequency signals. It is not uncommon to have sample rates in hundreds of Giga samples per second range. Processing the amount of data generated for useful applications such as displaying the waveform on the screen presents many challenges. For example, trigger logic captures only the record of samples in the region of interest. However, one challenge involves processing a record for every subsequent trigger. Therefore, the instrument holds off the trigger for a long period to allow time to process the data. In a real-time oscilloscope, this results in missing most of the triggers. This is also known as blind time.

To reduce blind time, the instrument can capture the waveform at a higher rate with a shorter trigger hold-off period and display it at a higher display refresh rate. Human eyes can distinguish waveforms only up to some finite rate. One solution uses a histogram of the waveforms where many waveforms are drawn stacked on top of each other per display refresh. Doing this requires drawing every triggered waveform at a very high rate, such as drawing the waveforms millions of times a second. Even the highest-end CPU and RAM do not have the processing performance to do this currently. Options such as a dedicated bare metal processor, FPGA (field-programmable gate array), or an ASIC (application specific integrated circuit) with an integrated memory may perform as needed but are expensive to develop.

### BRIEF DESCRIPTION OF THE DRAWINGS

FIG. 1 shows an embodiment of a test and measurement instrument.

FIG. 2 an embodiment of a histogram on a raster plane.

FIG. 3 shows pixel addresses with respect to a display orientation.

FIG. 4 shows a diagram of an embodiment of thread grouping and memory access pattern.

FIG. 5 shows an embodiment of a test waveform.

FIG. 6 shows a graph of a first relationship between throughput and update rate.

FIG. 7 shows a graph of a second relationship between the throughput and update rate.

FIG. 8 shows an embodiment of a simulated test waveform for a pulse-amplitude modulated (PAM4) signal.

### DESCRIPTION

Embodiments of the disclosure solve this problem by utilizing the processing power of a GPU (Graphics Processing Unit). In an example embodiment, a batch of waveform data is transferred over a communications bus, such as a PCIe bus, into the GPU RAM (random access memory). The GPU then rasterizes the digital waveforms to a histogram buffer. Embodiments of the disclosure may use a special rasterization algorithm to maximize the throughput rate. The GPU then transfers the histogram buffer contents back to the CPU (central processing unit) for further processing and display at a much slower display refresh rate.

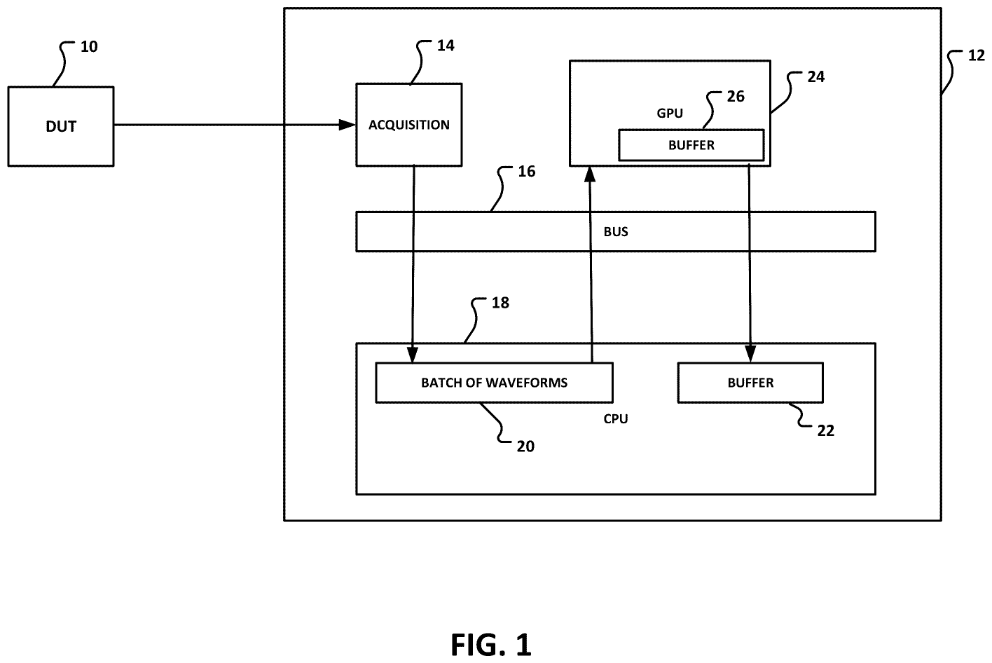

FIG. 1 shows a block diagram of a test and measurement instrument 12. The instrument includes a waveform digitizer in an acquisition system or circuit 14 having memory storage, a CPU 18, which may comprise a CPU on a motherboard with memory in the form of a buffer 20 and a raster plan 22, and a GPU 24 with memory 26. The waveform digitizer and the GPU may communicate with the CPU and motherboard memories using a bus 16.

The acquisition circuit or board 14 digitizes a batch of trigger waveforms from a device under test (DUT) 10. Acquisition circuit 14 may store the batch of digitized waveform in a memory that resides in the acquisition circuit, not shown. Each digitized waveform has a constant size. The batch consists of thousands of digitized waveforms. The size of acquisition buffer and the GPU buffer 26 limits the size of the batch. The acquisition system 14 transfers the batch to the CPU motherboard buffer 20. In another embodiment, the acquisition circuit can transfer the batch straight to the GPU via the bus, this does not seem to improve the overall throughput. The batch data can optionally be processed by the CPU before transferring it to the GPU buffer 26. The GPU rasterizes all waveforms in the batch to a GPU raster plane buffer 26 to form a waveform histogram for the entire batch. The GPU then transfers the finished raster plane back to the CPU motherboard. Th CPU can convert the histogram to a map for display. The map may comprise a heat map of colors, or a grey-scale map, etc.

The batch size impacts the overall throughput efficiency and the updates rate of the raster plane. More frequent display of the histogram requires a smaller batch size, but the overall efficiency improves with the larger batch size.

The instruments and methods of the embodiments use a GPU architecture that has multiple cores that can process in parallel. The effectiveness and the rasterization speed depend on the specific GPU architecture and model. For example, many GPUs use a multi-core, multi-threaded SIMD stream architecture. The memory system may of large DDR (double data rate) memory, and L1 and L2 cache. The speed of the processing depends heavily on how the memory is accessed. Each memory read generally corresponds to the size of the cache line, typically 128 bytes. Efficient use of all 128 bytes is highly desired.

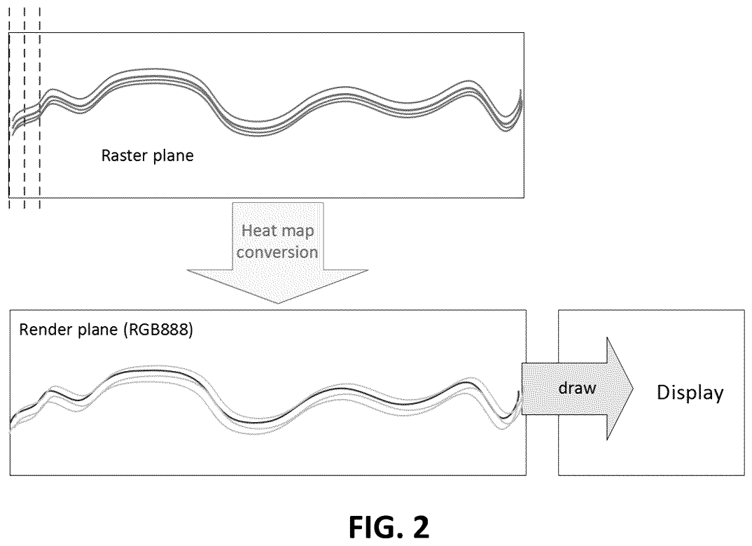

Embodiments of th disclsoure use a GPU processing algorithm that runs efficiently within the constraints of the GPU architecture. The rasterization method intends to best utilize the parallel processing architecture while minimizing cache load. FIG. 2 shows that the waveforms can be divided into pixel-wide columns. The GPU assignes each thread a specific column. In FIG. 2, the dotted line represents a pixel column. This is then converted to a heat map for display.

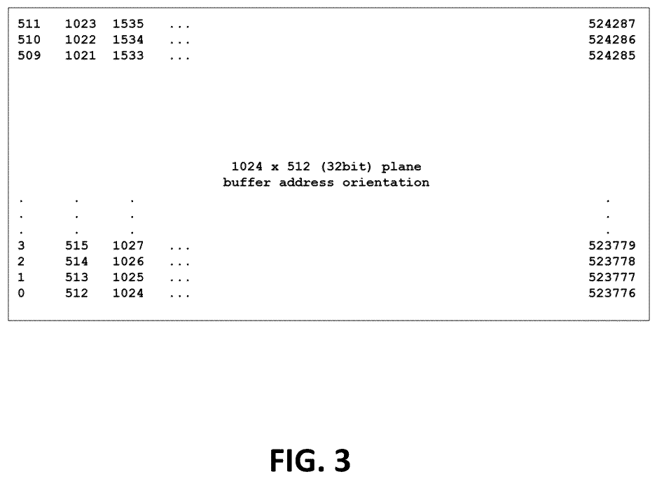

In an example embodiment, the raster plane comprises a 1024×512×32-bit pixel buffer in the GPU memory. This example uses specific dimensions and pixel depths to assist with understanding of the process and is not intended to limit the scope of the claims. The 32-bit pixels have addresses from 0 to 524287, which is 1024×512 number of pixels. FIG. 3 shows the relative pixel address in pixel units and where the pixels are displayed on the screen. This layout is cache-friendly for the rasterization process used here.

The example algorithm implementation herein is based on GLSL compute shader language. However, this can be applied to other GPU languages such as HSL, or CUDA™.

The algorithm may allow for optimization for specific GPU architectures. The embodiments here use architectures that support 32 or more parallel SIMD (Single Instruction Multiple Data) processing paradigms. The 32 SIMD processing lanes are expressed as 32 threads in the GPU software. Therefore, 32 SIMT (Single Instruction Multiple Threads) means the same thing as SIMD in the context of the GPU software. One should note that the 32 processors here could easily be 50 SIMD processors, etc.

The GPU may then group the 32 SIMD/SIMT processors as a first type of group, referred to here as an x-group. A second type of group, a y-group, has 1024 x-groups, one for each column in the raster plane, and the GPU may have many y-groups. The x-group that consists of 32 SIMD/SIMT processors exist physically in the GPU. However, the total number of x-groups and y-groups may not reflect the actual number of these 32 SIMD/SIMT processors in the GPU but it is rather a software abstraction. A GPU with thousands of cores can run many x-groups and y-groups concurrently whereas a GPU with a small number of cores cannot. This particularly dimensioned architecture supports a cache line of 128 bytes per thread for both read and writes. The input waveform is a read-only operation by the GPU and the output is a read-modify-write operation to the raster plane. The waveform typically has about 2048 bytes long. The optimum case is made if the algorithm does the least amount of cache loads and runs a common instruction for the duration of the thread.

The input data comprises a batch of waveforms. In this example, the waveforms consist of 1024 samples which correlate to the number of columns in the raster plane. Waveforms may have a different numbers of samples, and the corresponding raster plane may have different dimensions. The optimum batch size depends on PCIe bus speed, processing throughput of the GPU, and the display update rate. In this example, the batch size comprises 8192 waveforms.

The GPU draws every waveform in the batch on the raster plane by incrementing the target pixel by one. As the GPU iterates through the waveforms in the batch, the target pixel for a particular sample increases by one for every sample that ‘lands’ at that pixel position. This forms a histogram of ‘hits’ at a particular pixel position.

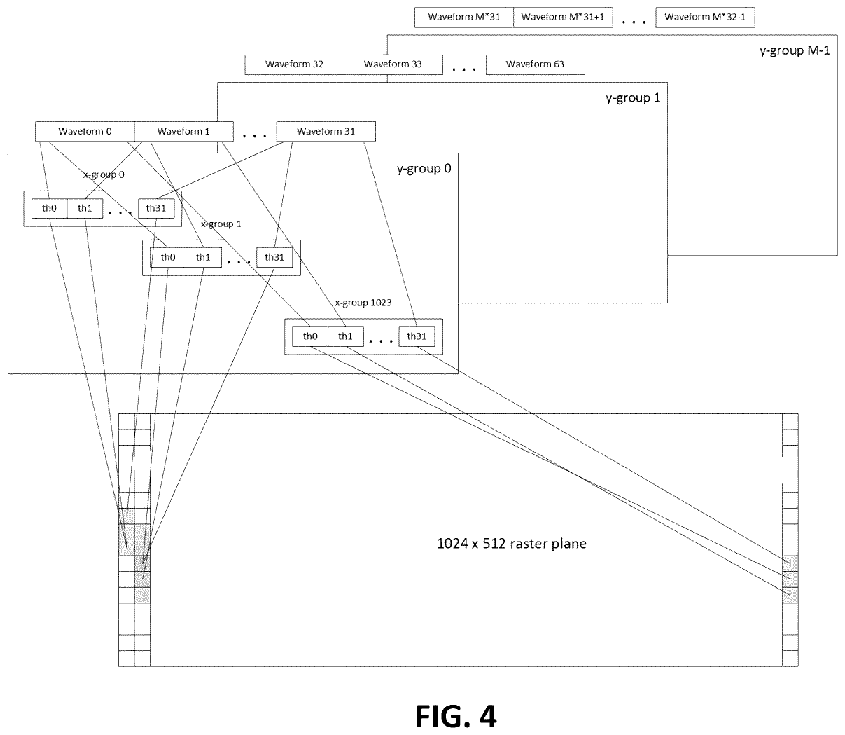

FIG. 4 shows a graphic representaiton of how the digitized waveforms map to the raster plane. For the particular numbers used here, every 32 consecutive waveforms which correlate to the number of SIMD processors in an x-group are assigned to each y-group indexed from 0 to 255. Looking at FIG. 4, the y-group 0 has x-groups 0 through 1023, one for every column. Each x-group comprises an instance of the 32 threads processing the digitized waveform data for 32 consecutive waveforms. For x-group 0 in y-group 0, each thread, th0 through th31, has one of the consecutive 32 waveforms. Each x-group is assigned a specific sample place on each waveform, and a specific column in the raster plane. This is from the 1^{st} to 1024^{th} sample. Each y-group has 1024 x-groups correlating to the 1024 columns in the raster plane. The 32 threads within a column would populate the column pixel positions with 32 samples, wherever those samples reside. Further waveform processing will populate the samples in the column that have ‘hits’ or data.

The configuration maximizes the use of the total number of processing cores available for the GPU, and minimizes the cache loads. The column will generally occupy a contiguous span of memory space. In the example above, a single read of the cache line of 128 bytes (128*8=1024) is sufficient.

The example above assumes a GPU having 32 SIMD machines data of 32 bits. The single SIMD runs the 32 threads in parallel. Multiple SIMDs may also run concurrently if the processing code operates them independently in a non-sequential fashion. Both the GPU and the CPU generally comprise processors that execute code, and the code causes the processors to operate as set out here.

As discussed above, the data size of the SIMD architecutre here has 32 floats, or floating point processors, where the “processor” may take the form of a process within a processing core of a GPU. In another example, the GPU could have 50 SIMD machines and would process 50 columns concurrently. In the representation of FIG. 4, this would be x-group 0 through x-group 49, then x-group 50 through x-group 99, until x-group 1000 to x-group 1023. The indexing of the groups does not loop with the iterations, such as re-using 0 through 49, to avoid sequentialization.

The following is an example algorithm in C code, according to some embodiments of the disclosure.

| | |
|---|---|
| H = 512 | // column height in pixel unit |
| nT = 32 | // number of parallel SIMD threads in a group. |
| | // this is 1 of nT x-groups |
| nX = 1024 | // number of x-groups, 1 for each column |
| nY = 256 | // number of y-groups, nWaveform = nY * nT |

There are two views of the configuration. First, the input data, raster plane, and threads are physically in linear order, configured to multiple dimensions. Second, the indices in the rightmost square bracket point to the smallest constituents in contiguous space.

Resource allocation:

| thread[nY][nX][nT] | |
|---|---|
| | // nT = number of threads in a group. |
| | // There are nY*nX groups in all |
| inData[nY][nT][nX] | // Total input data size = nY*nX*nT |
| raster[nX][H] | // Allocation for nX x H raster plane. |
| | // nX = number of columns |

The data access order, in which iT is the lowest order, then iX, then iY

thread[ iY{0..nY−1} ] [ iX{0..nX−1} ] [ iT{0..nT−1} ]

// 0 to (nT*nX*nY)−1 in linear index

inData[ iY{0..nY−1} ] [ iT{0..nT−1} ] [ iX{0..nX−1} ]

// 0 to (nX*nT*nY)−1

raster[ iX{0..nX−1} ] [ iH{0...H−1} ]

// 0 to (nX*H)−1

RL = 1024
inData = waveform[M * 32][1024]

Branchless main logic

| index = (iFrame * RL32) + x_index32; | |
|---|---|
| d32_1 = d32Waveform[index + 0]; | |
| d32_2 = d32Waveform[index + 1]; | |
| shift = x_index16 & 0x1; | //0 or 1 |
| bitShift = shift << 4; | //0 or 16 |

```
d1 = (d32_1 >> bitShift) & 0x3ff;
d2 = (((d32_1 >> 16) * (1-shift)) + ((d32_2 & 0x3ff) * shift));
//draw vertical line from d1 to d2
rastPos = (vertRes * x_index16) + d1;
h = d2 − d1;
//sgn( ) = −1 (if h<0), 0 (if h==0), or + 1 (if h>0)
dh = 3 + (2 * ((h>>31) − 1));
d32raster[rastPos] += 1;
for(ih = 0; ih != h; ih+=dh) {
  rastPos+=dh;
  d32 = d32raster[rastPos] + 1;
  d32raster[rastPos] = d32;
}
```

Within the 32 SIMD processors in a group, the main logic here does not diverge until the end.
The vertical line drawn to the raster plane can be different for each thread.

The inventors performed a test using a system consisting of an AMD EPYC CPU and a Quadro T1000 GPU on a PCIe Gen3 16x BUS.

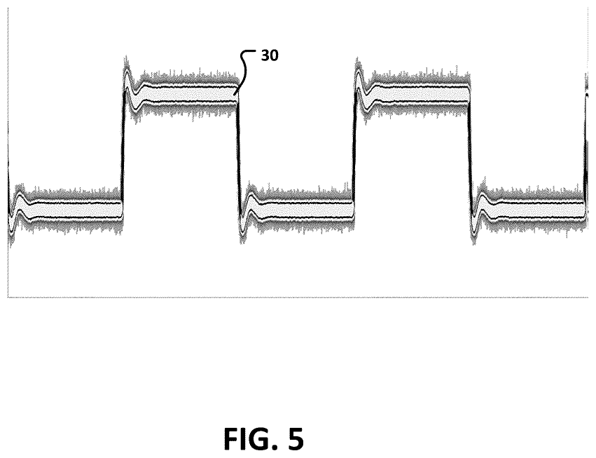

This benchmark measures the total throughput of the PCIe DMA, the GPU rasterization, the heat map conversion, and the display rendering via GPU. The test waveform 30 used is a simulated square waveform with simulated noise and jitter as shown in FIG. 5.

Table 1 below shows the benchmark results. The nX is the total number of x-groups and the nY is the total number of y-groups.

By adjusting the nY, one can change the batch size. The batch size has a direct impact on the display update rate shown in FPS (Frames Per Second) column. The column KAcqs/s is the acquisitions per sec in the thousands.

TABLE 1

| Dimension | 32 * nX * nY * 1 | nWaveform | FPS | KAcqs/s |
|---|---|---|---|---|
| 1024 × 512 | 32 × 1024 × 64 × 1 | 2048 | 60 | 122 |
| 1024 × 512 | 32 × 1024 × 128 × 1 | 4096 | 56 | 229 |
| 1024 × 512 | 32 × 1024 × 256 × 1 | 8192 | 46 | 376 |
| 1024 × 512 | 32 × 1024 × 512 × 1 | 16384 | 41 | 688 |
| 1024 × 512 | 32 × 1024 × 1024 × 1 | 32768 | 26 | 851 |
| 1024 × 512 | 32 × 1024 × 2048 × 1 | 65536 | 16 | 1048 |
| 1024 × 512 | 32 × 1024 × 4096 × 1 | 131072 | 9 | 1179 |

This demonstrates the ability to rasterize over 1 million acquisitions per second at 10 frames per second refresh rate.

The next benchmark removes the overhead of the direct memory access (DMA), heatmap conversion, and display. This more accurately demonstrates the GPU rasterization speed, with the results shown in Table 2.

TABLE 2
The rasterization throughput without the overhead of
DMA, heat map conversion, and the display rendering.

| Dimension | 32 * nX * nY * 1 | nWaveform | FPS | KAcqs/s |
|---|---|---|---|---|
| 1024 × 512 | 32 × 1024 × 64 × 1 | 2048 | 654 | 1347 |
| 1024 × 512 | 32 × 1024 × 128 × 1 | 4096 | 437 | 1789 |
| 1024 × 512 | 32 × 1024 × 256 × 1 | 8192 | 261 | 2138 |
| 1024 × 512 | 32 × 1024 × 512 × 1 | 16384 | 145 | 2375 |
| 1024 × 512 | 32 × 1024 × 1024 × 1 | 32768 | 76 | 2490 |
| 1024 × 512 | 32 × 1024 × 2048 × 1 | 65536 | 39 | 2555 |
| 1024 × 512 | 32 × 1024 × 4096 × 1 | 131072 | 20 | 2621 |

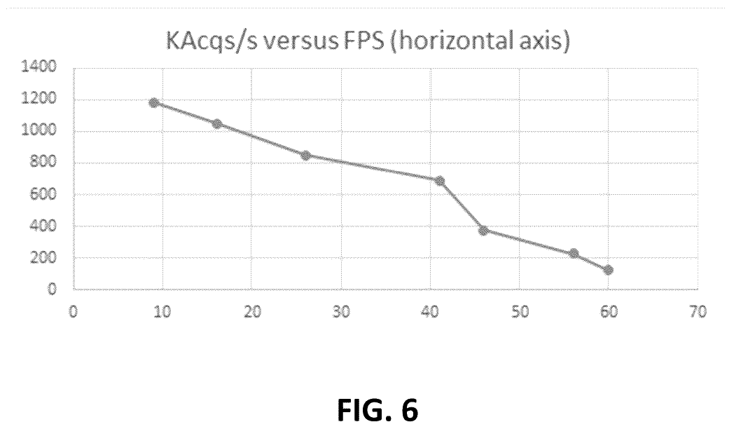

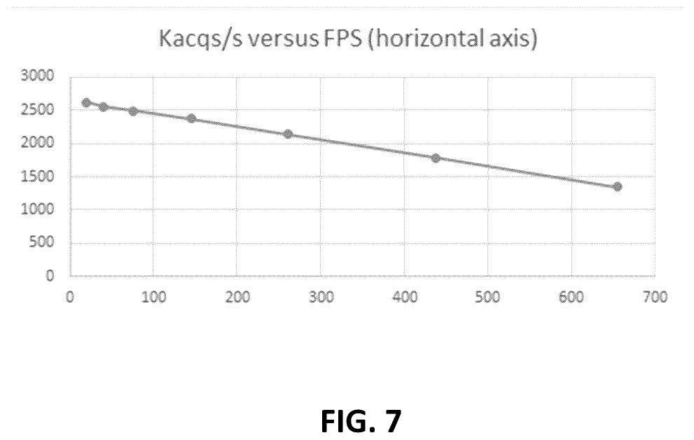

This demonstrates that with faster PCIe, faster heatmap conversion, and a display system, the acquisition rate can be much higher. There is a tradeoff between the update rate (Frames Per Second) and acquisitions per second as shown in FIGS. 6 and 7.

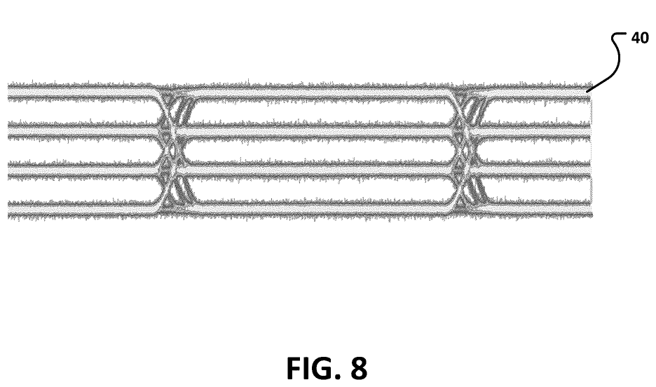

There is also a tradeoff between the waveform complexity and the throughput due to number of pixels drawn. The waveform 40 shown in FIG. 8 is slower by a factor of 2× than the waveform 30 of FIG. 5.

Aspects of the disclosure may operate on a particularly created hardware, on firmware, digital signal processors, or on a specially programmed general purpose computer including a processor operating according to programmed instructions. The terms controller or processor as used herein are intended to include one or more microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

The previously described versions of the disclosed subject matter have many advantages that were either described or would be apparent to a person of ordinary skill. Even so, these advantages or features are not required in all versions of the disclosed apparatus, systems, or methods.

### EXAMPLES

Illustrative examples of the disclosed technologies are provided below. An embodiment of the technologies may include one or more, and any combination of, the examples described below.

Example 1 is a test and measurement instrument, comprising: an acquisition system configured to receive and digitize a batch of waveforms from a device under test (DUT) into a batch of digitized waveforms; a memory configured as a raster plane having rows and columns; a graphics processing unit (GPU) capable of processing multiple threads, configured to execute code to cause the GPU to rasterize the batch of digitized waveforms to the raster plane to form a batch histogram and, for each digitized waveform, to cause the GPU to: group multiple threads into groups of a first type of group; assign each thread group of the first type of group to one column in the raster plane; execute a common instruction per thread group of the first type to populate the raster plane with data from the digitized waveform; and transfer the batch histogram upon completion; and a central processing unit (CPU) in communication with the GPU, the CPU configured to execute code to cause the CPU to: receive the batch histogram from the GPU; and display a map of the batch histogram on a display.

Example 2 is the test and measurement instrument of Example 1, wherein the CPU and the GPU are connected by a communications bus.

Example 3 is the test and measurement instrument of Example 2, wherein a size of the batch of waveforms depends upon the communication bus speed, processing throughput of the GPU and a display update rate.

Example 4 is the test and measurement instrument of any of Examples 1 through 3, wherein the CPU is configured to execute code to cause the CPU to receive the batch of digitized waveforms into a CPU buffer.

Example 5 is the test and measurement instrument of any of Examples 1 through 4, wherein the GPU is further configured to execute code to cause the GPU to receive the batch of digitized waveforms into one or more GPU buffers.

Example 6 is the test and measurement instrument of any of Examples 1 through 5, wherein the GPU is further configured to execute code to cause the GPU to group multiple groups of the first type of group into groups of a second type of group, a number of groups of the second type of group corresponding to a number of the columns in the raster plane.

Example 7 is the test and measurement instrument of any of Examples 1 through 6, wherein the GPU is further configured to execute code to cause the GPU to receive a number of consecutive digitized waveforms corresponding to a number of threads in the GPU.

Example 8 is the test and measurement instrument of Example 7, wherein the number of threads operate in parallel.

Example 9 is the test and measurement instrument of any of Examples 1 through 8 wherein the threads correspond to Single Instruction Multiple Data (SIMD) processors within the GPU.

Example 10 is the test and measurement instrument of any of Examples 1 through 9, wherein the code to cause the GPU to group multiple threads into groups of the first type of group causes the GPU to assign a specific sample place on each of the digitized waveforms to each group of the first type of group.

Example 11 is the test and measurement instrument of any of Examples 1 through 10, wherein the code to cause the GPU to rasterize the digitized waveforms causes the GPU to draw every waveform on the raster plane by incrementing a target pixel by one for each sample received for the target pixel.

Example 12 is the test and measurement instrument of any of Examples 1 through 11 wherein each column of the raster plane resides in a contiguous region of the memory.

Example 13 is a method of displaying waveform data, comprising: receiving a batch of waveforms from a device under test (DUT); digitizing the batch of waveforms to produce a batch of digitized waveforms; receiving the batch of digitized waveforms at a graphics processing unit (GPU) capable of processing multiple threads; rasterizing, by the GPU, the batch of digitized waveforms into a raster plane having rows and columns; grouping multiple threads into a first type of group; assigning each thread group of the first type of group to one column in the raster plane; executing a common instruction per thread group of the first type of group to populate the raster plane with data from the digitized waveform to form a batch histogram; and displaying a map of the batch histogram on a display.

Example 14 is the method of Example 13, wherein producing the batch of digitized waveforms comprises transferring the batch of digitized waveforms from the DUT to one of either a buffer on a central processing unit (CPU) or a buffer on the GPU.

Example 15 is the method of one of either Examples 13 or 14, further comprising grouping the groups of the first type of group into a number of groups of a second type of group corresponding to a number of the columns in the raster plane.

Example 16 is the method of any of Examples 13 through 15, wherein receiving the batch of digitized waveforms at the GPU comprises receiving a number of consecutive digitized waveforms corresponding to a number of threads in each GPU.

Example 17 is the method of any of Examples 13 through 16, wherein the multiple threads operate in parallel.

Example 18 is the method of any of Examples 13 through 17, wherein the threads correspond to Single Instruction Multiple Data (SIMD) processors within the GPU.

Example 19 is the method of any of Examples 13 through 18, wherein grouping multiple threads into groups of a first type of group comprises assigning a specific sample place on each of the digitized waveforms to each of the instances.

Example 20 is the method of any of Examples 13 through 19, wherein rasterizing the batch of digitized waveforms comprises drawing every waveform on the raster plane by incrementing a target pixel by one for every sample that resides at a position for that pixel.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
an acquisition system configured to receive and digitize a batch of waveforms from a device under test (DUT) into a batch of digitized waveforms;
a memory configured as a raster plane having rows and columns;
a graphics processing unit (GPU) capable of processing multiple threads, configured to execute code to cause the GPU to rasterize the batch of digitized waveforms to the raster plane to form a batch histogram and, for each digitized waveform, to cause the GPU to:
group multiple threads into groups of a first type of group;
assign each thread group of the first type of group to one column in the raster plane;
execute a common instruction per thread group of the first type to populate the raster plane with data from the digitized waveform; and
transfer the batch histogram upon completion; and
a central processing unit (CPU) in communication with the GPU, the CPU configured to execute code to cause the CPU to:
receive the batch histogram from the GPU; and
display a map of the batch histogram on a display.

2. The test and measurement instrument as claimed in claim 1, wherein the CPU and the GPU are connected by a communications bus.

3. The test and measurement instrument as claimed in claim 2, wherein a size of the batch of waveforms depends upon the communication bus speed, processing throughput of the GPU and a display update rate.

4. The test and measurement instrument as claimed in claim 1, wherein the CPU is configured to execute code to cause the CPU to receive the batch of digitized waveforms into a CPU buffer.

5. The test and measurement instrument as claimed in claim 1, wherein the GPU is further configured to execute code to cause the GPU to receive the batch of digitized waveforms into one or more GPU buffers.

6. The test and measurement instrument as claimed in claim 1, wherein the GPU is further configured to execute code to cause the GPU to group multiple groups of the first type of group into groups of a second type of group, a number of groups of the second type of group corresponding to a number of the columns in the raster plane.

7. The test and measurement instrument as claimed in claim 1, wherein the GPU is further configured to execute code to cause the GPU to receive a number of consecutive digitized waveforms corresponding to a number of threads in the GPU.

8. The test and measurement instrument as claimed in claim 7, wherein the number of threads operate in parallel.

9. The test and measurement instrument as claimed in claim 1, wherein the threads correspond to Single Instruction Multiple Data (SIMD) processors within the GPU.

10. The test and measurement instrument as claimed in claim 1, wherein the code to cause the GPU to group multiple threads into groups of the first type of group causes the GPU to assign a specific sample place on each of the digitized waveforms to each group of the first type of group.

11. The test and measurement instrument as claimed in claim 1, wherein the code to cause the GPU to rasterize the digitized waveforms causes the GPU to draw every waveform on the raster plane by incrementing a target pixel by one for each sample received for the target pixel.

12. The test and measurement instrument as claimed in claim 1, wherein each column of the raster plane resides in a contiguous region of the memory.

13. A method of displaying waveform data, comprising:
receiving a batch of waveforms from a device under test (DUT);
digitizing the batch of waveforms to produce a batch of digitized waveforms;
receiving the batch of digitized waveforms at a graphics processing unit (GPU) capable of processing multiple threads;
rasterizing, by the GPU, the batch of digitized waveforms into a raster plane having rows and columns;
grouping multiple threads into a first type of group;
assigning each thread group of the first type of group to one column in the raster plane;
executing a common instruction per thread group of the first type of group to populate the raster plane with data from the digitized waveform to form a batch histogram; and
displaying a map of the batch histogram on a display.

14. The method as claimed in claim 13, wherein producing the batch of digitized waveforms comprises transferring the batch of digitized waveforms from the DUT to one of either a buffer on a central processing unit (CPU) or a buffer on the GPU.

15. The method as claimed in claim 13, further comprising grouping the groups of the first type of group into a number of groups of a second type of group corresponding to a number of the columns in the raster plane.

16. The method as claimed in claim 13, wherein receiving the batch of digitized waveforms at the GPU comprises receiving a number of consecutive digitized waveforms corresponding to a number of threads in each GPU.

17. The method as claimed in claim 13, wherein the multiple threads operate in parallel.

18. The method as claimed in claim 13, wherein the threads correspond to Single Instruction Multiple Data (SIMD) processors within the GPU.

19. The method as claimed in claim 13, wherein grouping multiple threads into groups of a first type of group comprises assigning a specific sample place on each of the digitized waveforms to each of the instances.

20. The method as claimed in claim 13, wherein rasterizing the batch of digitized waveforms comprises drawing every waveform on the raster plane by incrementing a target pixel by one for every sample that resides at a position for that pixel.
